(19) United States
(12) Patent Application Publication
(10) Pub. No.: US 2003/0170560 A1
(43) Pub. Date: Sep. 11, 2003

(54) Decomposition type resin

(75) Inventors: Chih-Shin Chuang, Hsinchu (TW); Tsing-Tang Song, Ilan (TW); Weir-Torn Jiaang, Taipei (TW)

Correspondence Address: SUGHRUE MION, PLLC, 2100 PENNSYLVANIA AVENUE, N.W., WASHINGTON, DC, 20037, US

(73) Assignee: INDUSTRIAL TECHNOLOGY RESEARCH INSTITUTE

(21) Appl. No.: 10/287,738

(22) Filed: Nov. 5, 2002

(30) Foreign Application Priority Data
Jan. 14, 2002 (TW) 91100380

(51) Int. Cl. G03F 7/038

(52) U.S. Cl. 430/270.1; 430/905

(57) ABSTRACT

A decomposition type resin having the formula (I):

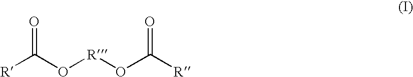

wherein R′ and R″ are acrylic series polymers or norbornene series polymers, R′″ is divalent C₁₋₂₀ linear or branched alkyl, C₃₋₂₀ cyclic alkyl, C₁₋₆ linear, branched or cyclic alkoxy, silyl, or alkylsilyl. The decomposition resin can be used to prepare photoresists. The contrast of the photoresist before and after exposure is increased, and the resolution is enhanced.

### BACKGROUND OF THE INVENTION

1. Field of the Invention:

The present invention relates to a decomposition type resin, and more particularly to a decomposition type resin that can produce photoresists with high resolution.

2. Background of the Invention:

Photoresist is very important in photolithography technique. The function of a photoresist is to transfer the circuit design pattern into the wafer surface. With the trend of increasing IC density, resolution demands on photoresist are increasing. Therefore, the development of superior photoresist material is a research focus in the industry.

The main development aspect of photoresist material is the copolymer of maleic anhydride and norbornene derivative. The glass transition temperature is increased and etch resistance is enhanced by improving the rigid structure of the copolymer. However, since the norbornene monomer has poor free radical polymerization reactivity, the obtained copolymer of norbornene monomer and maleic anhydride has a low molecular weight, less than 3000. Moreover, it is very difficult to improve the reactivity by changing either reaction temperature, reaction concentration or reaction time. Therefore, the photoresist obtained has poor etch resistance and resolution.

### SUMMARY OF THE INVENTION

The main object of the present invention is to provide a decomposition type resin, having the formula (I):

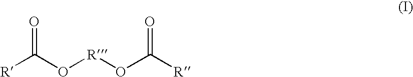

wherein

R′ and R″ are acrylic series polymers or norbornene series polymers,

R′″ is divalent C₁₋₂₀ linear or branched alkyl, C₃₋₂₀ cyclic alkyl, C₁₋₆ linear, branched or cyclic alkoxy, silyl, or alkylsilyl.

The decomposition type resin of the present invention increases the molecular weight by connecting a plurality of norbornene-maleic anhydride copolymerization long chains. Therefore, the decomposition type resin of the present invention produces photoresists with high etch resistance and resolution.

Another object of the present invention is to provide a photoresist composition, including:

(a) 5-20 wt % of the decomposition type resin of the present invention;

(b) 0.0015-2 wt % of an photoacid generator;

(c) 0.00003-0.1 wt % of an additive; and

(d) 100 wt % of a solvent.

### DETAILED DESCRIPTION OF THE INVENTION

The decomposition type resin of the present invention has the formula (I):

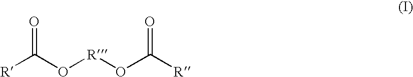

wherein

R′ and R″ are acrylic series polymers or norbornene series polymers,

R′″ is divalent C₁₋₂₀ linear or branched alkyl, C₃₋₂₀ cyclic alkyl, C₁₋₆ linear, branched or cyclic alkoxy, silyl, or alkylsilyl.

R′″ is an acid-decomposable protective group. The resin becomes alkaline soluble when the protective group is decomposed. R′″ is one of the following groups

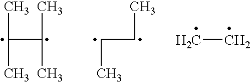

The decomposition type resin can be a copolymer represented by the formula (I-1) including four repeating units a, b, c, and d

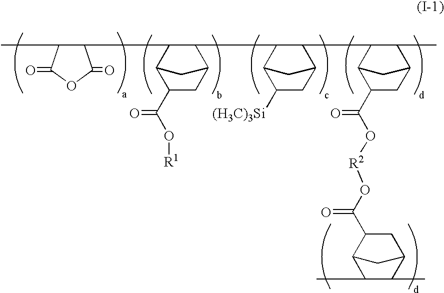

wherein

R¹ and R² is C₁₋₂₀ linear or branched alkyl, C₃₋₂₀ cyclic alkyl, C₁₋₆ linear, branched or cyclic alkoxy, silyl, or alkylsilyl, and

the molar ratio of the repeating units a, b, c, and d is 1:0.01-0.5:0.01-0.5:0.01-0.3.

Specifically, the four monomers constituting the repeating units a, b, c, and d can be respectively

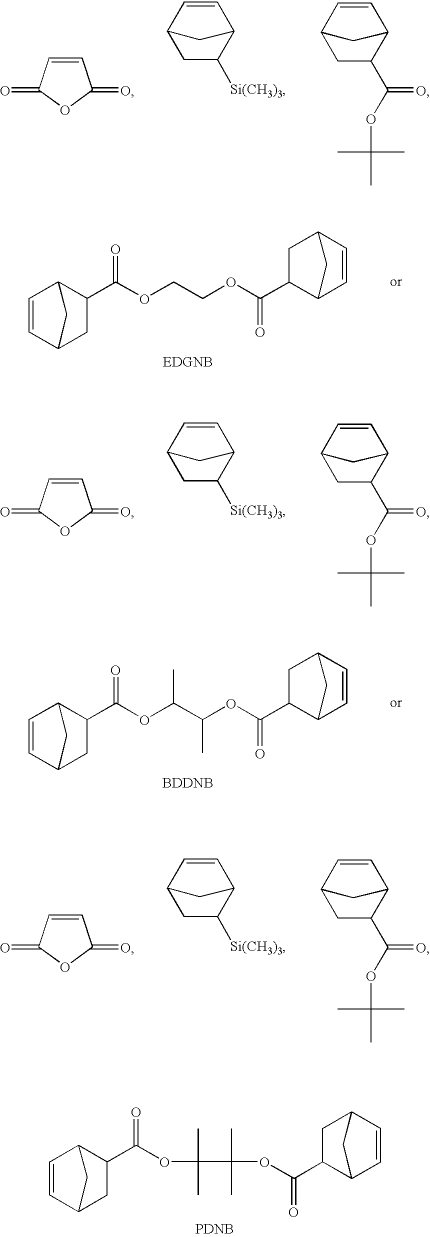

Or, alternatively, the decomposition type resin of the present invention can be a copolymer represented by the formula (I-2) including three repeating units a, b, and d

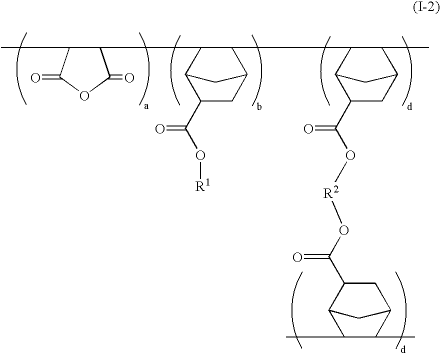

wherein

R¹ and R² is C₁₋₂₀ linear or branched alkyl, C₃₋₂₀ cyclic alkyl, C₁₋₆ linear, branched or cyclic alkoxy, silyl, or alkylsilyl, and

the molar ratio of the repeating units a, b, and d is 1:0.01-0.5:0.01-0.3.

Specifically, the three monomers constituting the repeating units a, b, and d are respectively

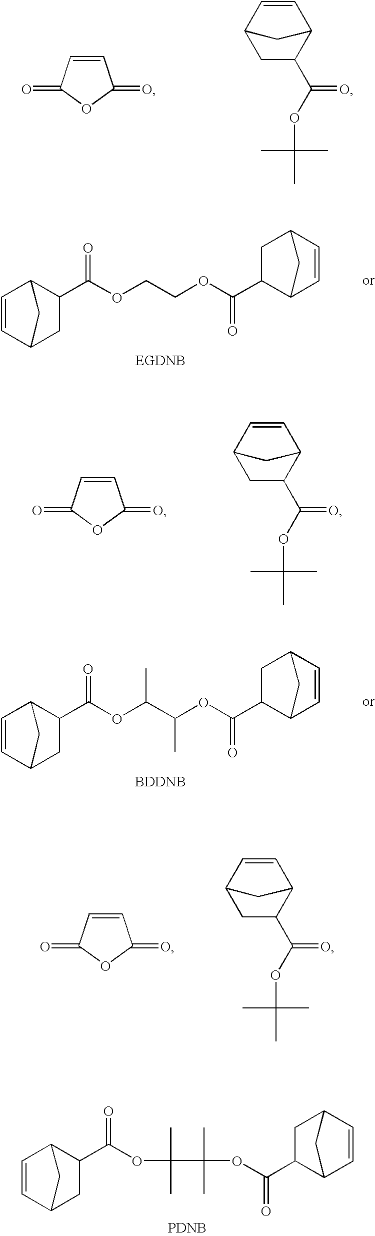

Or, alternatively, the decomposition type resin of the present invention is a copolymer represented by the formula (I-3) including two repeating units a and d

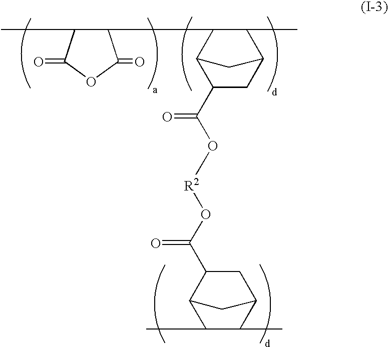

wherein

R² is C₁₋₂₀ linear or branched alkyl, C₃₋₂₀ cyclic alkyl, C₁₋₆ linear, branched or cyclic alkoxy, silyl, or alkylsilyl, and

the molar ratio of the repeating units a and d is 1:0.01-0.3.

The monomers constituting the two repeating units a and d are respectively

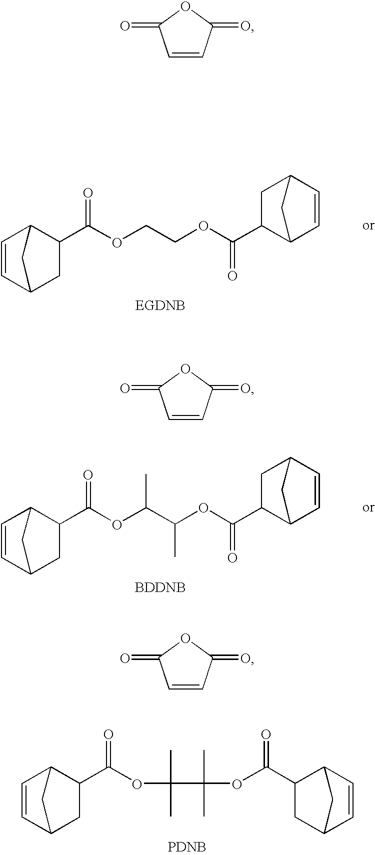

In addition, the decomposition type resin of the present invention can be dissolved in an organic solvent and preferably has a weight average molecular weight (Mw) of 2000 to 20000. Preferably, the decomposition type resin has a glass transition temperature (Tg) of 70° C. to 200° C.

According to the present invention, the norbornene monomer and maleic anhydride are copolymerized in an alternative way to obtain the decomposition type resin. Since the norbornene monomer has two norbornene structures in one molecule, each of these two norbornene structures can be respectively polymerized with maleic anhydride via free radical polymerization. Thus, a plurality of copolymerization long chains are connected, and the copolymer obtained has increased molecular weight. Therefore, the decomposition type resin of the present invention produces photoresists with enhanced etch resistance and resolution.

The photoresist composition of the present invention includes:

(a) 5-20 wt % of the decomposition type resin of the present invention;

(b) 0.0015-2 wt % of an photoacid generator;

(c) 0.00003-0.1 wt % of an additive; and

(d) 100 wt % of a solvent.

The additive (c) can be trialkyl amine or trialkyl substituted amine.

Representative examples of the photoacid generator (b) include

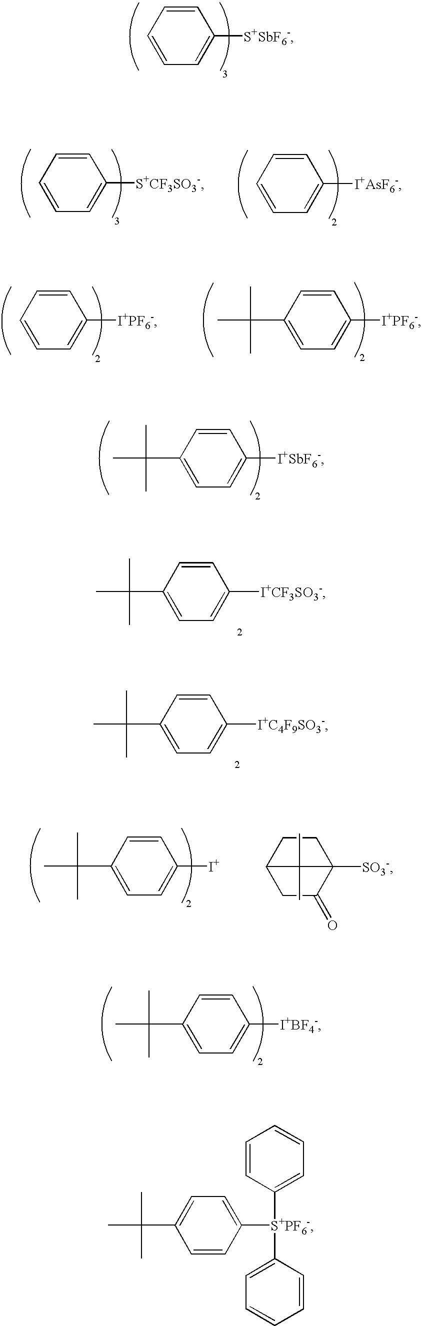

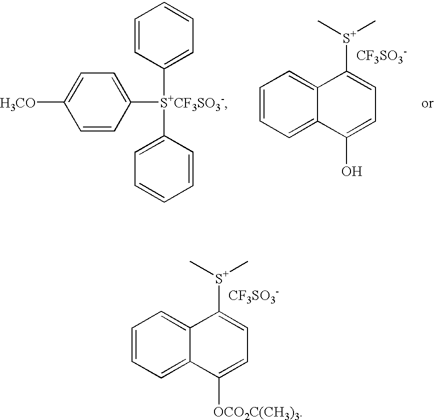

The solvent (d) can be at least one of the following components: ethers, ethylene glycol ether, aromatic hydrocarbons, ketones, and esters. That is to say, the solvent (d) can be a single organic solvent, or a mixture of two or more organic solvents. Specifically, representative examples of the solvent (d) include toluene, propylene glycol methyl ether acetate, methyl isobutyl ketone, ethyl lactate, and cyclohexanone.

Before exposure, the photoresist composition of the present invention includes the copolymer of norbornene monomer and maleic anhydride, which has high molecular weight cross-linked polymeric long chains. After exposure, the cross-linked polymeric long chains rapidly decompose into small molecular weight fragments. The great change on molecular weight before and after exposure can increase the resolution of the photoresist. Therefore, the photoresist composition of the present invention can produce photoresists with high etch resistance and resolution.

The following examples are intended to illustrate the process and the advantages of the present invention more fully without limiting its scope, since numerous modifications and variations will be apparent to those skilled in the art.

### EXAMPLE 1

Preparation of Norbornene Monomer EGDNB

40 g (0.44 mol) of acrylol chloride was charged in a 1 liter three-necked bottle equipped with a refluxing tube. 100 ml of dicyclopentadiene was charged in a 100 ml three-necked bottle. The 100 ml three-necked bottle was equipped with a distillation tube and connected to the 1 liter bottle. Next, the 1 liter bottle was introduced with nitrogen and placed in an ice bath. The 100 ml bottle was heated to 166° C. to 170° C. to decompose dicyclopentadiene into cyclopentadiene. 30 g (0.44 mol) of the obtained cyclopentadiene was added dropwise to the 1 liter bottle over 12 hours. Next, 300 ml of dehydrated tetrahydrofuran was added to the 1 liter bottle.

Subsequently, 12.4 g (0.2 mol) of ethylene glycol, 41 g (0.4 mol) of dehydrated triethylamine, trace amount of 4-dimethylamine pyridine, and 400 ml of dehydrated tetrahydrofuran were mixed thoroughly and added dropwise to the 1 liter bottle. The reaction proceeded at room temperature for 12 hours. Next, the reaction mixture was evaporated under reduced pressure to remove tetrahydrofuran, had 1.5 liter of deionized water added, was extracted with ether, and was dried with magnesium sulfate. Next, the reaction mixture was evaporated under reduced pressure to remove ether, and purified with column chromatography (eluent is hexane/ethyl acetate=1/10) to obtain EGDNB (45.3 g, yield=75%).

### EXAMPLE 2

Preparation of Norbornene Monomer BDDNB

30 g (0.33 mol) of acrylol chloride was charged in a 1 liter three-necked bottle equipped with a refluxing tube. 100 ml of dicyclopentadiene was charged in a 100 ml three-necked bottle. The 100 ml three-necked bottle was equipped with a distillation tube and connected to the 1 liter bottle. Next, the 1 liter bottle was introduced with nitrogen and placed in an ice bath. The 100 ml bottle was heated to 166° C. to 170° C. to decompose dicyclopentadiene into cyclopentadiene. 22.5 g (0.33 mol) of the obtained cyclopentadiene was added dropwise to the 1 liter bottle over 10 hours. Next, 300 ml of dehydrated tetrahydrofuran was added to the 1 liter bottle.

Subsequently, 13.5 g (0.15 mol) of 2,3-butylene glycol, 31 g (0.3 mol) of dehydrated triethylene amine, trace amount of 4-dimethylamine pyridine, and 400 ml of dehydrated tetrahydrofuran were mixed thoroughly and added dropwise to the 1 liter bottle. The reaction proceeded at room temperature for 12 hours. Next, the reaction mixture was evaporated under reduced pressure to remove tetrahydrofuran, had 1.5 liter of deionized water added, was extracted with ether, and was dried with magnesium sulfate. Next, the reaction mixture was evaporated under reduced pressure to remove ether, and purified with column chromatography (eluent is hexane/ethyl acetate=1/10) to obtain BDDNB (19.2 g, yield=39%).

### EXAMPLE 3

Preparation of Norbornene Monomer PDNB

30 g (0.33 mol) of acrylol chloride was charged in a 1 liter three-necked bottle equipped with a refluxing tube. 100 ml of dicyclopentadiene was charged in a 100 ml three-necked bottle. The 100 ml three-necked bottle was equipped with a distillation tube and connected to the 1 liter bottle. Next, the 1 liter bottle was introduced with nitrogen and placed in an ice bath. The 100 ml bottle was heated to 166° C. to 170° C. to decompose dicyclopentadiene into cyclopentadiene. 22.5 g (0.33 mol) of the obtained cyclopentadiene was added dropwise to the 1 liter bottle over 10 hours. After the reaction was complete, the reaction mixture was held still for 12 hours to cool down slowly to room temperature. Next, 300 ml of dehydrated tetrahydrofuran was added to the 1 liter bottle.

Subsequently, 17.7 g (0.15 mol) of pinacol, 31 g (0.3 mol) of dehydrated triethylene amine, trace amount of 4-dimethylamine pyridine, and 400 ml of dehydrated tetrahydrofuran were mixed thoroughly and added dropwise to the 1 liter bottle. The reaction proceeded at room temperature for 12 hours. Next, the reaction mixture was evaporated under reduced pressure to remove tetrahydrofuran, had 1.5 liter of deionized water added, was extracted with ether, and was dried with magnesium sulfate. Next, the reaction mixture was evaporated under reduced pressure to remove ether, and purified with column chromatography (eluent is hexane/ethyl acetate=1/10) to obtain PDNB (36.3 g, yield=68%).

### EXAMPLE 4

Preparation of Acrylic Monomer Pinacol Diacrylate (PDA)

30 g (0.33 mol) of acrylol chloride was charged in a 1 liter three-necked bottle equipped with a refluxing tube. 300 ml of dehydrated tetrahydrofuran was then added.

Subsequently, 17.7 g (0.15 mol) of pinacol, 31 g (0.3 mol) of dehydrated triethylene amine, trace amount of 4-dimethylamine pyridine, and 400 ml of dehydrated tetrahydrofuran were mixed thoroughly and added dropwise to the 1 liter bottle. The reaction proceeded at room temperature for 6 hours. Next, the reaction mixture was evaporated under reduced pressure to remove tetrahydrofuran, and then purified with reduced pressure distillation to afford PDA (34.6 g, yield=77%).

### EXAMPLE 5

Resin A

7.4 g (0.075 mol) of maleic anhydride (MA), 6.8 g (0.035 mol) of t-butyl 5-norbornene-2-carboxylate (TBNB), and 2.3 g (0.0075 mol) of monomer EGDNB were dissolved in 20 ml of tetrahydrofuran (THF) under nitrogen. The solution was stirred thoroughly and heated to 70° C. Next, 1.15 g (0.005 mol) of initiator dimethyl-2,2′-azobisisobutyrate (V-601) was dissolved in 2 ml of THF and then injected with a syringe into the 70° C. reaction solution. Next, the reaction mixture was stirred at 70° C. for 10 hours. After the reaction was complete, the the reaction mixture was diluted with THF, precipitated in water two times, filtered, and dried under vacuum at 50° C. for 12 hours to afford Resin A (yield=99%).

Finally, Resin A was determined on molecular weight with GPC (WATERS Model 600) and determined on thermal properies with DSC (PERKIN ELMER DSC7) and TGA (PERKIN ELMER TGA7). The results were: molecular weight=4258, Tg=143° C., and Td=202° C.

### EXAMPLE 6

Resin B

3.92 g (0.04 mol) of maleic anhydride (MA), 2.33 g (0.012 mol) of t-butyl 5-norbornene-2-carboxylate (TBNB), 3.32 g (0.02 mol) of 5-norbornene trimethylsilane (TSNB), and 1.44 g (0.004 mol) of monomer PDNB were dissolved in 20 ml of THF under nitrogen. The solution was stirred thoroughly and heated to 70° C. Next, 1.15 g (0.005 mol) of initiator V-601 was dissolved in 2 ml of THF and then injected with a syringe into the 70° C. reaction solution. Next, the reaction mixture was stirred at 70° C. for 10 hours. After the reaction was complete, the the reaction mixture was diluted with THF, precipitated in water two times, filtered, and dried under vacuum at 50° C. for 12 hours to afford Resin B (yield=97%).

Finally, Resin B was determined on molecular weight with GPC (WATERS Model 600) and determined on thermal properies with DSC (PERKIN ELMER DSC7) and TGA (PERKIN ELMER TGA7). The results were: molecular weight=4477, Tg=156° C., and Td=199° C.

### EXAMPLE 7

Resin C

1.7 g (0.0075 mol) of PDA, 8.52 g (0.06 mol) of t-butyl methacrylate, 14.2 9 (0.0825 mol) of (trimethylsilane)methyl methacrylate were dissolved in 40 ml of THF under nitrogen. The solution was stirred thoroughly and heated to 70° C. Next, 1.15 g (0.005 mol) of initiator V-601 was dissolved in 2 ml of THF and then injected with a syringe into the 70° C. reaction solution. Next, the reaction mixture was stirred at 70° C. for 10 hours. After the reaction was complete, the the reaction mixture was diluted with THF, precipitated in water two times, filtered, and dried under vacuum at 50° C. for 12 hours to afford Resin C (yield=99%).

Finally, Resin C was determined on molecular weight with GPC (WATERS Model 600) and determined on thermal properies with DSC (PERKIN ELMER DSC7) and TGA (PERKIN ELMER TGA7). The results were: molecular weight=86487, Tg=124° C., and Td=201° C.

### EXAMPLE 8

Preparation of Photoresists A and B

1.7 g of Resin A, 0.051 g of photoacid generator triphenylsulfonium nonafluorosulfate, 0.0012 g of 1-piperidine ethanol, and 11 g of PGMEA were and stirred thoroughly and then filtered with a 0.2 mm PTFE filter. Photoresist A was obtained.

The same procedures were employed except that the resin used was Resin B. Photoresist B was obtained.

Coating of the Resin Underlayer

2.5 ml of PFI38A9 photoresist available from Sumitomo was spin coated on an 8-inch wafer using a Polaris 2000 Microlithography Cluster Coater at 5000 rpm. The wafer was baked at 250° C. for 2 minutes to generate thermal curing. Then, the wafer was cooled to 23° C. and a resin underlayer 5000 Å thick was obtained.

Photolithographic Evaluation of the Photoresist

2 ml of photoresist A obtained from Example 8 was spin coated on the silicon wafer with the resin underlayer at 3000 rpm and baked at 130° C. for 90 seconds. Then, the wafer was cooled to 23° C. and a top photoresist layer of 2000 Å was obtained. The coated wafer was exposed through a mask using a 0.6 NA ISI 193nm Stepper and then subjected to post-exposure baking (PEB) at 120° C. to 150° C. for 90 seconds. The wafer was then cooled to 23° C. and developed for 60 seconds using 0.262 N tetramethylammonium hydroxide (TMAH) solution. The wafer was then rinsed with distilled water and spin dried to form a resist pattern.

The above procedures were repeated using photoresist B.

It was confirmed by scanning electron microscopy (SEM) that the photoresist B could resolve line-and-space patterns (L/S patterns) as small as 0.15 μm or even less. The photoresist top layer and resin underlayer showed good film forming properties and adhesion. The coated wafer had high photosensitive properties and the dose-to-clear energy (E₀) was 3-6 mJ/cm².

Dry Etching

The pattern of the photoresist top layer was transferred to the resin underlayer by dry etching. The dry etching conditions were as follows: 500 W (Source), 75 W (Bias), −10° C., 10 mT pressure, 20 scCm O₂ flow, 30 sccm SO₂ flow, and 30 seconds. For photoresist B, images from SEM after etching showed that the wall angle was larger than 88° and the resolution (CD; critical dimension) was smaller than 0.15 μm.

Evaluation Results

The other evaluation results for Resins A and B are shown in Table 1. OD indicates optical density, Eₜₕ the minimum dose-to-clear energy, and DE dark erosion.

TABLE 1

| Resin | Resin A | Resin B |
|---|---|---|
| MA (mol %) | 64 | 53 |
| TBNB (mol %) | 30 | 16 |
| TSNB (mol %) | — | 26 |
| PDNB (mol %) | — | 5 |
| EGDNB | 6 | — |
| PEB (° C.) | 160 | 130 |
| OD¹ (μm⁻¹) | 0.51 | 0.55 |
| Eₜₕ (mJ/cm²) | 11.7 | 3.0 |
| DE² (Å) | 306 | 463 |

For Resin A, when the PEB temperature of Resin A is 130° C., development cannot be achieved. When the PEB temperature is raised to 160° C., development can be achieved, but the Eₜₕ required is as high as 11.7 mJ/cm², and DE is 306 Å. For Resin B, development can be achieved when the PEB temperature is 130° C. and Eₜₕ is 3 mJ/cm². DE is 463 Å and resolution is 0.11 μm.

The foregoing description of the preferred embodiments of this invention has been presented for purposes of illustration and description. Obvious modifications or variations are possible in light of the above teaching. The embodiments chosen and described provide an excellent illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A decomposition type resin, having the formula (I) wherein 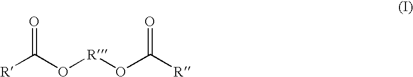
R′ and R″ are acrylic series polymers or norbornene series polymers,
R′″ is divalent C₁₋₂₀ linear or branched alkyl, C₃₋₂₀ cyclic alkyl, C₁₋₆ linear, branched or cyclic alkoxy, silyl, or alkylsilyl.

2. The decomposition type resin as claimed in claim 1, wherein R′″ is one of the following groups

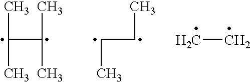

3. The decomposition type resin as claimed in claim 1, wherein the decomposition type resin is a copolymer represented by the formula (I-1) including repeating units a, b, c, and d 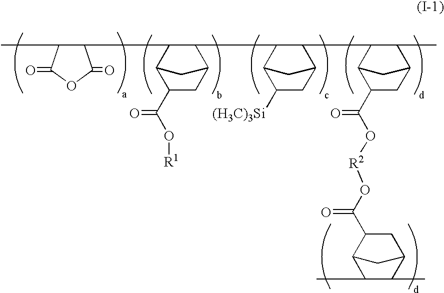
wherein
R¹ and R² is C₁₋₂₀ linear or branched alkyl, C₃₋₂₀ cyclic alkyl, C₁₋₆ linear, branched or cyclic alkoxy, silyl, or alkylsilyl, and
the molar ratio of the repeating units a, b, c, and d is 1:0.01-0.5:0.01-0.5:0.01-0.3.

4. The decomposition type resin as claimed in claim 3, wherein the monomers constituting the repeating units a, b, c, and d are respectively

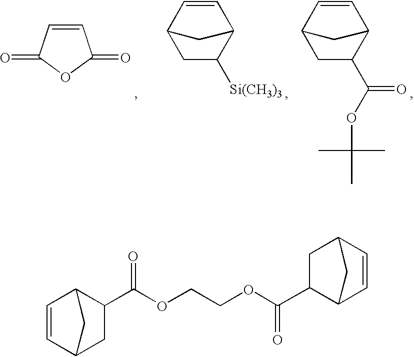

5. The decomposition type resin as claimed in claim 3, wherein the monomers constituting the repeating units a, b, c, and d are respectively

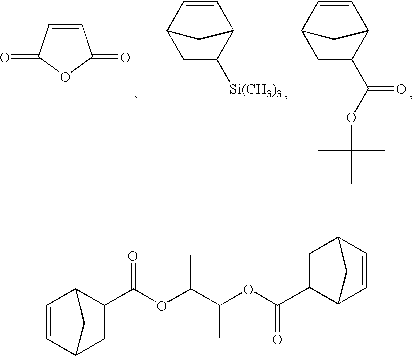

6. The decomposition type resin as claimed in claim 3, wherein the monomer constituting the repeating units a, b, c, and d are respectively

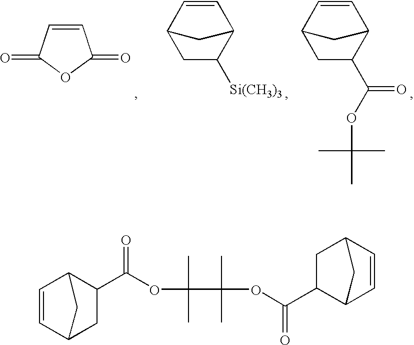

7. The decomposition type resin as claimed in claim 1, wherein the decomposition type resin is a copolymer represented by the formula (I-2) including repeating units a, b, and d 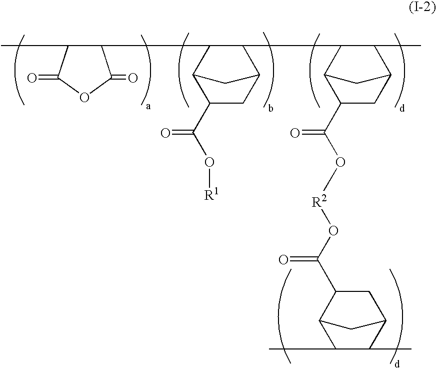
wherein
R¹ and R² is C₁₋₂₀ linear or branched alkyl, C₃₋₂₀ cyclic alkyl, C₁₋₆ linear, branched or cyclic alkoxy, silyl, or alkylsilyl, and
the molar ratio of the repeating units a, b, and d is 1:0.01-0.5:0.01-0.3.

8. The decomposition type resin as claimed in claim 7, wherein the monomers constituting the repeating units a, b, and d are respectively

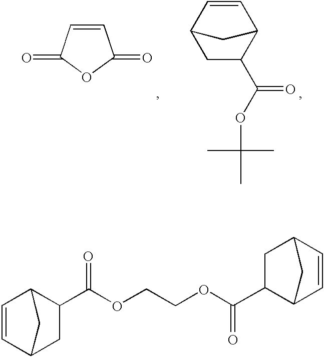

9. The decomposition type resin as claimed in claim 7, wherein the repeating units a, b, and d are respectively

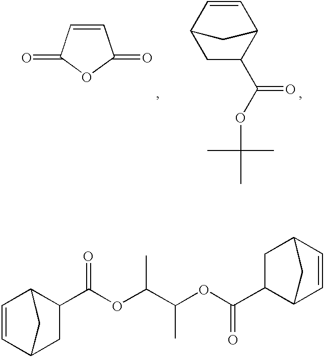

10. The decomposition type resin as claimed in claim 7, wherein the repeating units a, b, and d are respectively

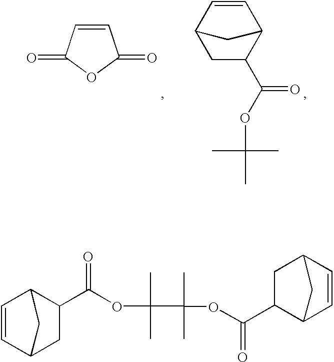

11. The decomposition type resin as claimed in claim 1, wherein the decomposition type resin is a copolymer represented by the formula (I-3) including repeating units a and d 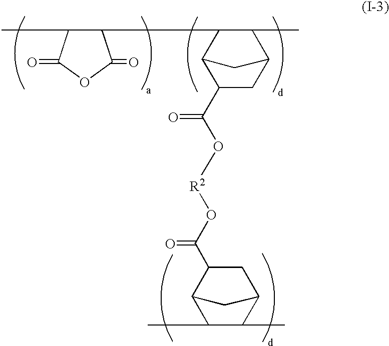
wherein
R² is C₁₋₂₀ linear or branched alkyl, C₃₋₂₀ cyclic alkyl, C₁₋₆ linear, branched or cyclic alkoxy, silyl, or alkylsilyl, and
the molar ratio of the repeating units a and d is 1:0.01-0.3.

12. The decomposition type resin as claimed in claim 11, wherein the repeating units a and d are respectively

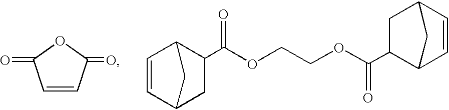

13. The decomposition type resin as claimed in claim 11, wherein the repeating units a and d are respectively

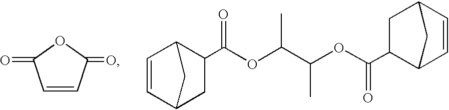

14. The decomposition type resin as claimed in claim 11, wherein the repeating units a and d are respectively

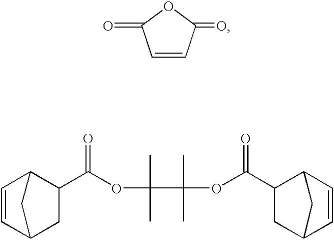

15. The decomposition type resin as claimed in claim 1, wherein the decomposition type resin has a weight average molecular weight (Mw) of 2000 to 20000.

16. The decomposition type resin as claimed in claim 1, wherein the decomposition type resin has a glass transition temperature (Tg) of 70° C. to 200° C.

17. A photoresist composition, comprising:
(a) 5-20 wt % of the decomposition type resin as claimed in claim 1;
(b) 0.0015-2 wt % of an photoacid generator;
(c) 0.00003-0.1 wt % of an additive; and
(d) 100 wt % of a solvent.

18. The photoresist composition as claimed in claim 17, wherein the additive (c) is trialkyl amine or trialkyl substituted amine.

19. The photoresist composition as claimed in claim 17, wherein the photoacid generator (b) is

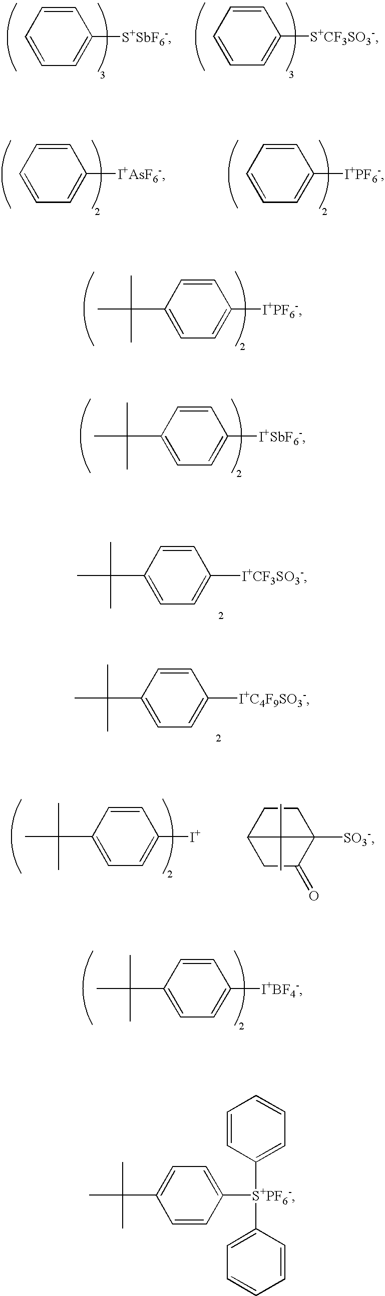

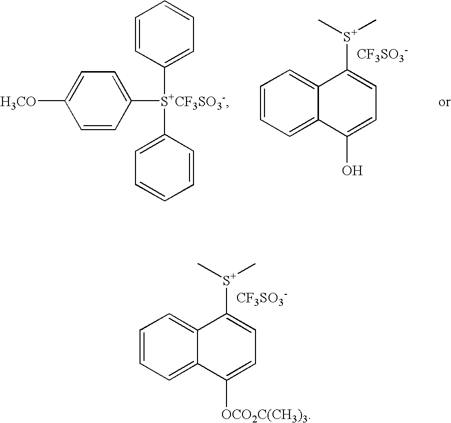

20. The photoresist composition as claimed in claim 17, wherein the solvent (d) is at least one of the following components: ethers, ethylene glycol ether, aromatic hydrocarbons, ketones, and esters.

21. The photoresist composition as claimed in claim 20, wherein the solvent (d) is toluene, propylene glycol methyl ether acetate, methyl isobutyl ketone, ethyl lactate, or cyclohexanone.
